(19) United States
(12) Patent Application Publication
(10) Pub. No.: US 2013/0118672 A1
(43) Pub. Date: May 16, 2013

(54) SUBSTRATE BONDING METHOD

(71) Applicants: Ho Joon Park, Gyunggi-do (KR); Kyung Wook Paik, Daejeon (KR); Young Jae Kim, Gyunggi-do (KR); Seung Ho Kim, Daejeon (KR); Ki Won Lee, Daejeon (KR)

(72) Inventors: Ho Joon Park, Gyunggi-do (KR); Kyung Wook Paik, Daejeon (KR); Young Jae Kim, Gyunggi-do (KR); Seung Ho Kim, Daejeon (KR); Ki Won Lee, Daejeon (KR)

(73) Assignees: KOREA ADVANCED INSTITUTE OF SCIENCE & TECHNOLOGY, Daejeon (KR); SAMSUNG ELECTRO-MECHANICS CO., LTD., Gyunggi-do (KR)

(21) Appl. No.: 13/615,813

(22) Filed: Sep. 14, 2012

(30) Foreign Application Priority Data
Nov. 16, 2011 (KR) 10-2011-0119805

(51) Int. Cl. H05K 3/00

(52) U.S. Cl. 156/73.1; 156/60

(57) ABSTRACT

Disclosed herein is a substrate bonding method including stacking a plurality of bonding objects including anisotropic conductive films (ACFs) and flexible printed circuit boards (FPCBs), which are sequentially stacked, on a substrate including bonding surfaces having a plurality of steps, according to the plurality of steps of the bonding surfaces of the substrate, and pressurizing the plurality of bonding objects to the substrate by a bonding tool of a bonding unit having pressurization surfaces having a shape corresponding to the bonding surfaces of the substrate to bond the plurality of bonding objects to each other.

### CROSS REFERENCE TO RELATED APPLICATION

This application claims the benefit of Korean Patent Application No. 10-2011-0119805, filed on Nov. 16, 2011, entitled “Substrate Bonding Method”, which is hereby incorporated by reference in its entirety into this application.

### BACKGROUND OF THE INVENTION

1. Technical Field

The present invention relates to a substrate bonding method.

2. Description of the Related Art

Bonding using polymer composites is utilized for various components such as an anisotropic conductive adhesive, an isotropic conductive adhesive, a non-conductive adhesive, an underfill resin, a thermal interface material, and the like, in an electronic component packaging field.

However, as the structure of component bonding parts in which such polymer composites are utilized has increasingly become complicated, the use of an existing method adaptive for a flat bonding surface involves a problem that a bonding process is required be performed several times to result in a degradation of productivity.

In particular, recently, a bonding surface of an anisotropic conductive adhesive between a touch panel and a flexible printed circuit board used in mobile phones has a step due to a difference in height in many cases. Thus, in an existing scheme, when a substrate including bonding parts having a step (or steps) due to a difference in height is bonded, respective portions of the substrate are required to be separately bonded, by avoiding a boundary portion of the step, in order to applying a uniform temperature and pressure to the respective portions, so productivity is considerably lowered.

### SUMMARY OF THE INVENTION

The present invention has been made in an effort to uniformly bond a substrate and a flexible printed circuit board to each other by using an anisotropic conductive film.

The present invention has also been made in an effort to quickly perform bonding even when a bonding part of a substrate has a step.

According to a preferred embodiment of the present invention, there is provided a substrate bonding method including: stacking a plurality of bonding objects including anisotropic conductive films (ACFs) and flexible printed circuit boards (FPCBs), which are sequentially stacked, on a substrate including bonding surfaces having a plurality of steps, according to the plurality of steps of the bonding surfaces of the substrate; and pressurizing the plurality of bonding objects to the substrate through a bonding tool of a bonding unit having pressurization surfaces with a shape corresponding to the bonding surfaces of the substrate to bond the plurality of bonding objects to each other.

The pressurization surfaces may include a plurality of protrusion portions and recess portions.

A lateral section of each of the protrusion portions and recess portions may have a quadrangular shape.

The bonding unit may be an ultrasonic bonding machine.

The bonding unit may be a hot press machine generating heat during a pressurization operation.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a flow chart illustrating a substrate bonding method according to an embodiment of the present invention; and

FIGS. 2 through 4 are cross-sectional views sequentially showing a substrate bonding method according to an embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

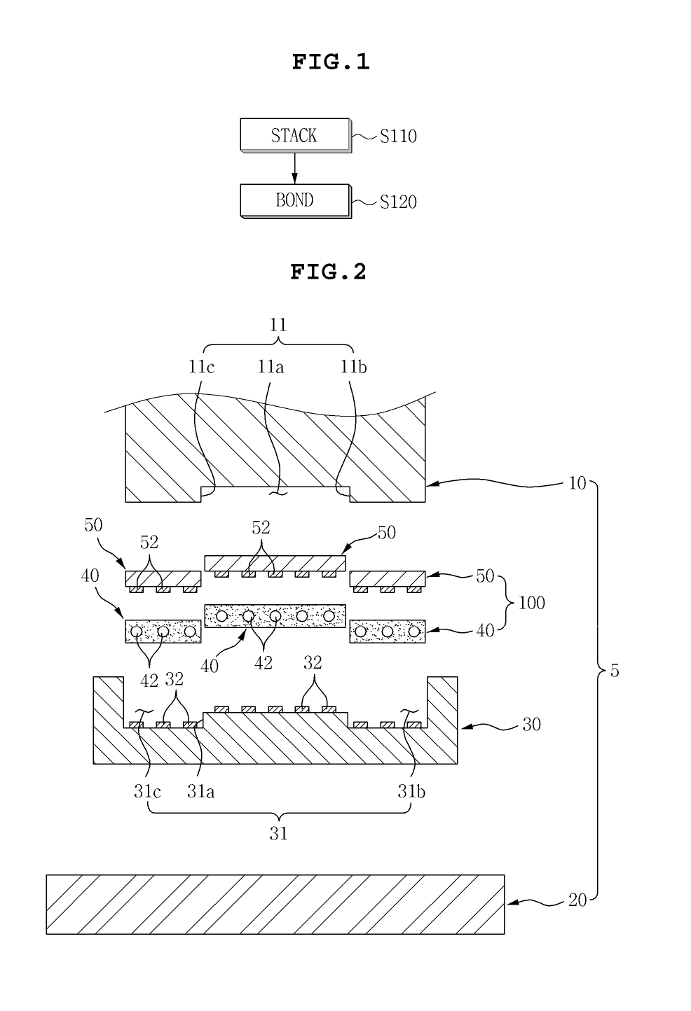

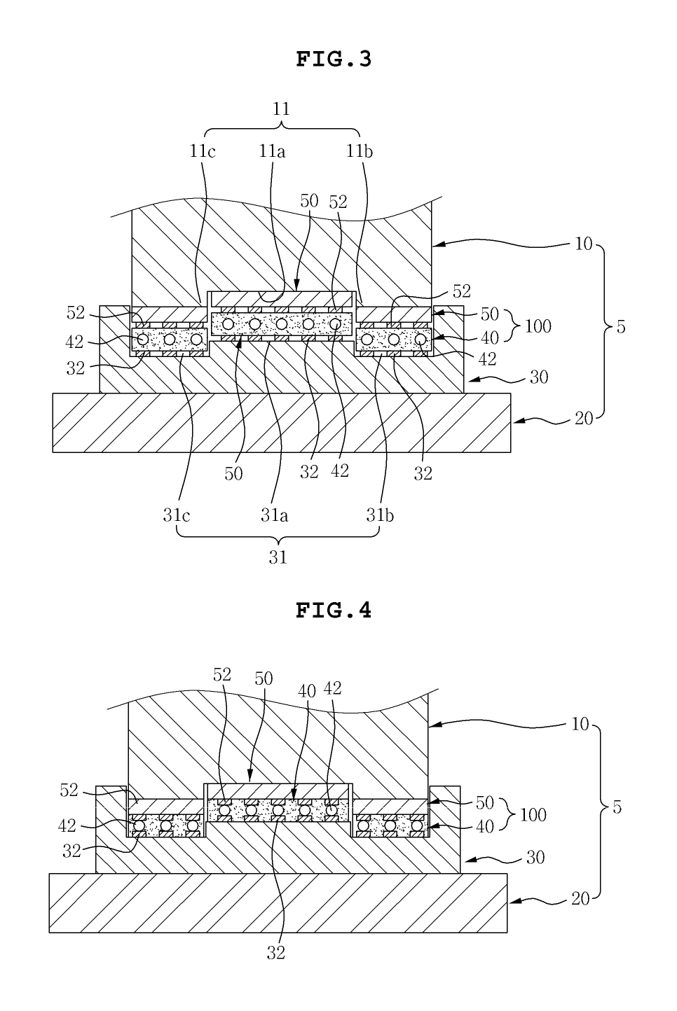

FIG. 1 is a flow chart illustrating a substrate bonding method according to an embodiment of the present invention, and FIGS. 2 through 4 are cross-sectional views sequentially showing a substrate bonding method according to an embodiment of the present invention.

Here, FIG. 2 is a cross-sectional view showing a state before bonding parts are stacked at a stacking stage of a substrate bonding method according to an embodiment of the present invention, FIG. 3 is a cross-sectional view showing a state after the bonding parts are stacked at the stacking stage of the substrate bonding method according to an embodiment of the present invention, and FIG. 4 is a cross-sectional view showing a state in which bonding parts are bonded in a bonding step of the substrate bonding method according to an embodiment of the present invention.

With reference to FIG. 1, in the substrate bonding method according to an embodiment of the present invention including a stacking step and a bonding step, a substrate 30, and a flexible printed circuit board (FPCB) 50 are bonded to each other by using an anisotropic conductive film 40.

Hereinafter, the substrate bonding method according to an embodiment of the present invention will be described in detail with reference to FIGS. 1 through 4.

### PREFERRED EMBODIMENT

With reference to FIGS. 2 and 3, in a stacking step (S110), the substrate 30, the anisotropic conductive films (ASFs) 40, flexible printed circuit boards (FPCBs) 50, and the like, are sequentially stacked on a stage 20 of a bonding unit 5. In addition, a bonding tool 10 of the bonding unit 5 is positioned on upper surfaces of the FPCBs 50.

Here, bonding surfaces 31 include a plurality of convex portions 31a and a plurality of concave portions 31b and 31c. A cross-section of the convex portion 31a and the concave portions 31b and 31c may have, for example, a quadrangular shape, but the shape of the bonding surface 31 of the substrate 30 according to an embodiment of the present invention is not necessarily limited thereto.

In addition, a plurality of bonding objects 100 including the ACFs 40 and the FPCBs 50 are provided and respectively stacked on the bonding surfaces 31 of the substrate 30 such that they correspond to a plurality of steps. Here, the plurality of bonding objects 100 are stacked on upper surfaces of the plurality of convex portions 31a and the plurality of concave portions 31b and 31c formed on the adherend of the substrate 30, respectively, and the bonding tool 10 is positioned on an upper surface of the bonding objects 100.

The bonding tool 10 includes pressurization surfaces 11 corresponding to the plurality of height steps formed on the bonding surfaces 31 of the substrate 30.

Here, the pressurization surfaces 11 are formed to include a recess portion 11a and protrusion portions 11b and 11c. A cross section of each of the recess portion 11a and the protrusion portions 11b and 11c may have, for example, a quadrangular shape, but the shape of the pressurization surface 10 of the bonding tool 10 according to an embodiment of the present invention is not limited thereto.

Meanwhile, the substrate 30 is configured as a transparent substrate of a touch panel, but the substrate 30 according to an embodiment of the present invention is not necessarily limited thereto. Here, the transparent substrate may be made of polyethylene terephthalate (PET), polyethylene naphthalate (PEN), polyether sulfone (PES), glass, tempered glass, polycarbonate (PC), a cyclic olefin polymer (COC), polymethylmethacrylate (PMMA), triacetylcellulose (TAC), biaxially oriented polystyrene (BOPS) containing a K resin, or a mixture thereof, and a transparent film obtained by stacking them.

Also, first electrodes 32 are formed on an upper surface of the substrate 30, and second electrodes 52 are formed on a lower surface of the FPCBs 50, so the first electrodes 32 and the second electrodes 52 are in contact with upper and lower surfaces of the ASFs 40.

The ASFs 40 each include an insulating resin and a plurality of conductive particles 42 distributedly formed within the insulating resin.

Here, the conductive particles 42 may be formed, for example, as metal particles such as gold (Au), nickel (Ni), or the like, or plastic particles coated with gold (Au)/nickel (Ni), but the material of the conductive particles 42 of the present invention is not limited thereto.

With reference to FIG. 4, in the bonding step S120, the bonding objects 100 including the ACFs 40 and the FPCBs 50 stacked on the substrate 30 are bonded to each other through the bonding tool 10 of the bonding unit 5.

The bonding tool 10 includes the pressurization surfaces 11 corresponding to the bonding surfaces 31 of the substrate 30 having a plurality of steps. Thus, when the bonding objects 100 and the substrate 30 are pressurized by the bonding tool 10, pressurization force is uniformly applied to the plurality of stacked bonding objects 100 such as the plurality of ACFs 40, the plurality of FPCBs 50, and the like, according to the plurality of steps formed on the bonding surfaces 31 of the substrate 30. Here, when the bonding objects 100 are pressurized by the bonding tool 10, the bonding unit 5 generates heat and transfers the generated heat to the bonding objects 100 through the bonding tool 10 to cure the ACFs 30, thus easily bonding the bonding objects 100.

Accordingly, pressure and temperature act uniformly on the bonding objects 100 and the substrate 30, whereby the substrate 30, the ACFs 40, and the FPCBs 50 are uniformly bonded.

Also, accordingly, deformation of the mutually adjacent portions of the plurality of bonding objects 100 generated when the plurality of bonding objects 100 are pressurized due to the plurality of steps formed on the bonding surfaces 31 of the substrate 30 can be prevented.

In addition, since the plurality of bonding objects 100 are pressurized to be bonded with the substrate 30 at a time by using the bonding tool 10, a bonding process time is shortened and productivity can be increased.

Meanwhile, when the bonding objects 100 are pressurized through the bonding unit 5, a compressive force is applied to each of the substrate 30, the FPCBs 50, and the ACFs 40, so the recess portions 31b and 31c as dented are formed on both side surfaces of the ACFs 40 by the first electrodes 32 and the second electrodes 52 formed to be protruded from the upper portion of the substrate 30 and the lower portion of the FPCBs 50, respectively.

Here, the first electrodes 32 and the second electrodes 52 of the substrate 30 and the FPCBs 50 are electrically connected to each other by the plurality of conductive particles 42 positioned in the ACFs 40.

Also, the bonding unit 5 is configured as a hot press machine or an ultrasonic bonding machine.

Here, the hot press machine generates heat from the bonding tool 10 to transmit the generated heat to the bonding objects 100 when the bonding objects 100 are pressurized. Here, the substrate 30 and the FPCBs 50 may be bonded by the ACFs 40 by virtue of heat transmitted to the ACFs 40 of the bonding objects 100.

Meanwhile, the ultrasonic bonding machine generates ultrasonic waves from the bonding tool 10 and transmits the generated ultrasonic waves to the bonding objects 100 when the bonding objects 100 are pressurized. Here, ultrasonic waves of 20 to 40 Hz are transmitted to the bonding objects 100 for 5 to 12 seconds through the bonding tool 10. Accordingly, ultrasonic waves acting on the bonding objects 100 causes friction to be generated, and 20,000 or greater number of times of friction generates heat to bond the bonding objects 100 to each other. However, the frequency of ultrasonic waves acting on the bonding objects 100 through the bonding tool of the ultrasonic bonding machine, the time for transmitting ultrasonic waves, and the temperature of generated heat according to an embodiment of the present invention are not limited thereto.

According to the embodiments of the present invention, when the FPCBs having steps are bonded to the substrate including the bonding part having steps, the bonding tool corresponding to the steps of the substrate is used, thus rapidly performing the bonding process and increasing productivity.

Also, an occurrence of a phenomenon in which physical properties of bonding objects are weakened and defective bonding occurs due to heat is transmitted to the bonding surfaces of contiguous bonding objects several times because the bonding tool is used several times due to the steps due to a difference in height in the bonding part can be prevented.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A substrate bonding method comprising:
stacking a plurality of bonding objects including anisotropic conductive films (ACFs) and flexible printed circuit boards (FPCBs), which are sequentially stacked, on a substrate including bonding surfaces having a plurality of steps, according to the plurality of steps of the bonding surfaces of the substrate; and
pressurizing the plurality of bonding objects to the substrate by a bonding tool of a bonding unit having pressurization surfaces having a shape corresponding to the bonding surfaces of the substrate to bond the plurality of bonding objects to each other.

2. The method as set forth in claim 1, wherein the pressurization surfaces include a plurality of protrusion portions and recess portions.

3. The method as set forth in claim 1, wherein a lateral section of each of the protrusion portions and recess portions has a quadrangular shape.

4. The method as set forth in claim 1, wherein the bonding unit is an ultrasonic bonding machine.

5. The method as set forth in claim 1, wherein the bonding unit is a hot press machine generating heat during a pressurization operation.
